(19) United States
(12) Patent Application Publication
(10) Pub. No.: US 2025/0112095 A1
(43) Pub. Date: Apr. 3, 2025

(54) SEMICONDUCTOR DEVICE AND METHOD OF MANUFACTURING THE SAME

(71) Applicant: Mitsubishi Electric Corporation, Tokyo (JP)

(72) Inventor: Kazufumi OKI, Tokyo (JP)

(73) Assignee: Mitsubishi Electric Corporation, Tokyo (JP)

(21) Appl. No.: 18/764,447

(22) Filed: Jul. 5, 2024

(30) Foreign Application Priority Data
Sep. 28, 2023 (JP) 2023-166799

(51) Int. Cl. H01L 21/66; H01L 21/56; H01L 23/00; H01L 23/28

(52) U.S. Cl. CPC H01L 22/12; H01L 21/56; H01L 23/28; H01L 24/48; H01L 24/49; H01L 2224/48245; H01L 2224/49

(57) ABSTRACT

An object is to provide a technique callable of determining whether or not a wire is nearly broken. A semiconductor device includes a semiconductor element, a terminal, a main wire electrically connected between the semiconductor element and the terminal, a dummy wire, and sealing resin. Both ends of the dummy wire are connected to portions where both ends of the main wire are connected, and tensile strength of the dummy wire itself is lower than that of the main wire itself. The sealing resin covers the semiconductor element, the main wire, and the dummy wire.

### BACKGROUND OF THE INVENTION

### Field of the Invention

The present disclosure relates to a semiconductor device and a method of manufacturing the semiconductor device.

### Description of the Background Art

Various techniques are proposed for detecting a state of a wire in a semiconductor device such as a power semiconductor device. For example, proposed in Japanese Patent Application Laid-Open No. 2005-286009 is a technique of detecting connection strength between a wire of a dummy wiring and a terminal to prevent detachment due to aging deterioration.

### SUMMARY

In a molding process of molding sealing resin in a process of manufacturing a semiconductor device, when molding resin having high viscosity in a melting state is injected into a mold, a wire connected to a terminal, for example, is subjected to viscosity resistance, and the wire is nearly broken in some cases. However, the wire covered by the sealing resin cannot be visually confirmed after the molding process, thus there is a problem that it is difficult to determine whether or not the wire is nearly broken.

The present disclosure therefore has been made to solve the above problems, and it is an object of the present disclosure to provide a technique capable of determining whether or not a wire is nearly broken.

A semiconductor device according to the present disclosure includes: a semiconductor element; a terminal; a main wire electrically connected between the semiconductor element and the terminal; a dummy wire having both ends connected to portions where both ends of the main wire are connected and having tensile strength of itself lower than tensile strength of the main wire itself; and sealing resin covering the semiconductor element, the main wire, and the dummy wire.

It can be determined whether or not the wire is nearly broken.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a configuration of a semiconductor device according to an embodiment 1.

FIG. 2 is a circuit diagram illustrating the configuration of the semiconductor device according to the embodiment 1.

FIG. 3 is a flow chart illustrating a method of manufacturing the semiconductor device according to the embodiment 1.

FIG. 4 is a plan view for explaining an inspection process according to the embodiment 1.

FIG. 5 is a diagram for explaining the inspection process according to the embodiment 1.

FIG. 6 is a plan view illustrating a configuration of a semiconductor device according to an embodiment 2.

### DESCRIPTION OF THE PREFERRED EMBODIMENTS

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter. A specific position and direction such as “upper side”, “lower side”, “left”, “right”, “front side”, or “back side”, for example, may not necessarily coincide with a position and direction in an actual implementation in the description hereinafter.

### Embodiment 1

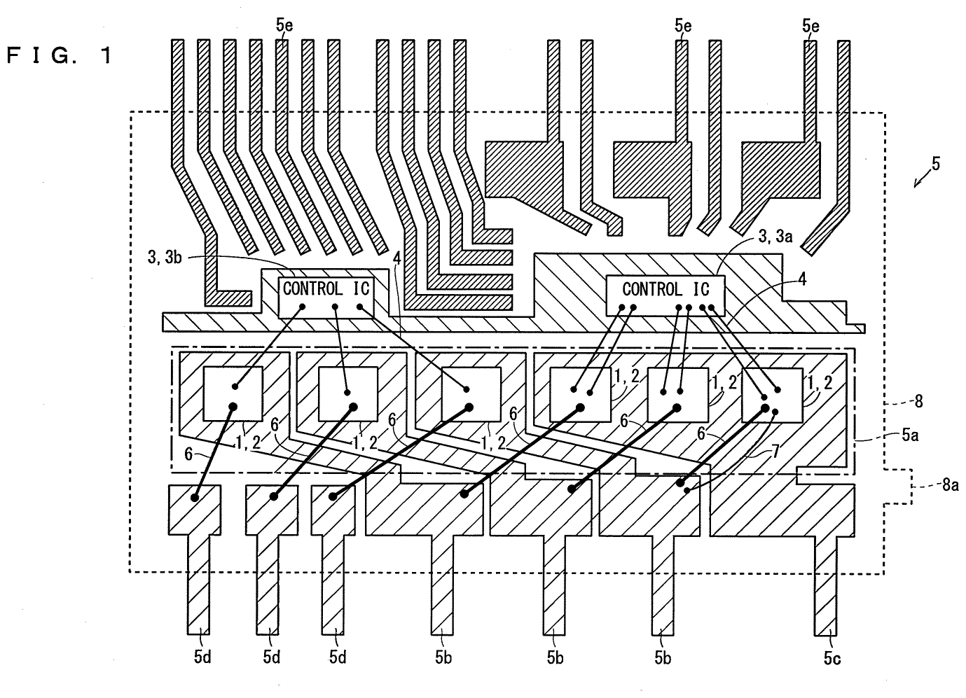

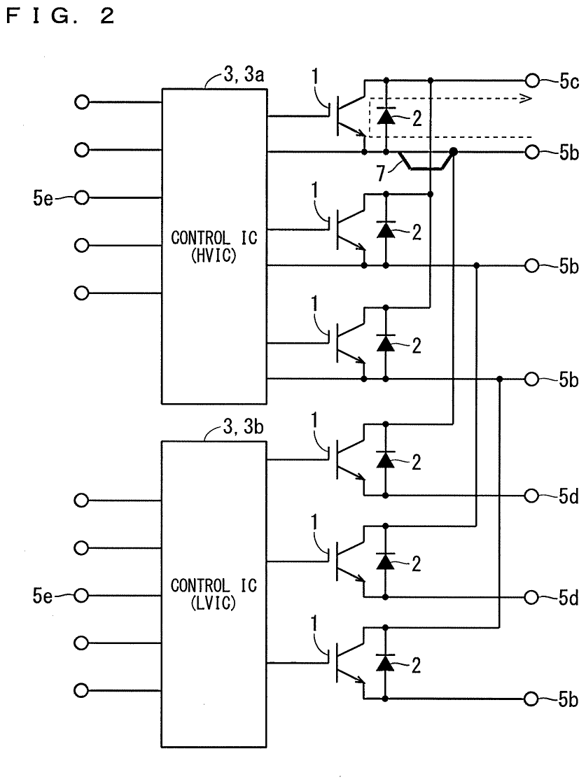

FIG. 1 is a plan view illustrating a configuration of a semiconductor device according to the present embodiment 1, and FIG. 2 is a circuit diagram illustrating the configuration thereof. The semiconductor device according to the present embodiment 1 includes a semiconductor switching element las a semiconductor element, a diode 2, a control integrated circuit (IC) 3, a control wire 4, a lead frame 5, a main wire 6, a dummy wire 7, a heatsink not shown in the diagrams, and sealing resin 8 as molding resin as illustrated in FIG. 1.

The semiconductor switching element 1, the diode 2, and the control IC 3 are made up of a semiconductor chip. The semiconductor chip may be made of normal silicon (Si), or may also be made of wide bandgap semiconductor such as silicon carbide (SIC), gallium nitride (GaN), or diamond. When the semiconductor chip is made up of wide bandgap semiconductor, a stable operation of the semiconductor chip under high temperature and high voltage and increase in switching speed can be achieved.

The semiconductor switching element 1 includes a control terminal not shown in the diagrams, and turns on and off power conduction between both ends of the semiconductor switching element 1 based on a control signal inputted to the control terminal. The semiconductor switching element 1 includes at least one of an insulated gate bipolar transistor (IGBT) and a metal oxide semiconductor field effect transistor (MOSFET), for example. In the present specification, at least one of A, B, C, . . . , and Z indicates any one of all of combinations of one type or more from a group of A, B, C, . . . , and Z.

As illustrated in FIG. 2, the diode 2 is connected in parallel to the semiconductor switching element 1. The diode 2 includes at least one of a Schottky barrier diode (SBD) and a PN junction diode (PND), for example. The diode 2 may be provided to one semiconductor chip together with the semiconductor switching element 1 such as a reverse conducting-IGBT (RC-IGBT), for example. FIG. 1 illustrates a configuration of providing the semiconductor switching element 1 and the diode 2 to one semiconductor chip, and this configuration is mainly described hereinafter as an example.

The control IC 3 generates a control signal for controlling power conduction of the semiconductor switching element 1. Details of the control IC 3 are described hereinafter.

The control wire 4 is electrically connected between the semiconductor switching element 1 and the control IC 3, and transmits a control signal for controlling the power conduction of the semiconductor switching element 1 from the control IC 3 to a control terminal of the semiconductor switching element 1.

The lead frame 5 constitutes a wiring inside the sealing resin 8 together with the control wire 4 and the main wire 6. The lead frame 5 is a conductive material, and includes a plurality of components obtained by dividing a conductive member such as a metal plate in accordance with a circuit configuration by pressing, for example.

At least one of the semiconductor chip of the semiconductor switching element 1 and the diode 2 and the semiconductor chip of the control IC 3 is mounted on the lead frame 5, and is bonded by soldering and a bonding member such as resin, for example. A part of the lead frame 5 to which the semiconductor switching element 1 is bonded is used as a die pad 5a, and an outer part of the sealing resin 8 is used as terminals 5a to 5e. A structure of preventing the bonding member from excessively spreading may be provided on the die pad 5a bonded to the semiconductor chip so as to surround the semiconductor chip.

The semiconductor device according to the present embodiment 1 is a semiconductor device having three phases, that is U-phase, V-phase, and W-phase. Thus, the die pad 5a includes a U-phase die pad, a V-phase die pad, a W-phase die pad, and a P-side die pad.

The U-phase die pad is connected to a terminal 5b as a U terminal, the V-phase die pad is connected to the terminal 5b as a V terminal, the W-phase die pad is connected to the terminal 5b as a W terminal, and the P-side die pad is connected to a terminal 5c as a P terminal. One semiconductor switching element 1 is mounted on each of the U-phase, V-phase, and W-phase die pads, and three semiconductor switching elements 1 are mounted in parallel to each other on the P-side die pad.

The main wire 6 is electrically connected between one of three semiconductor switching elements 1 mounted on the P-side die pad and one of the terminals (terminal 5b) of the U terminal, the V terminal, and the W terminal. The other main wire 6 is electrically connected between one semiconductor switching element 1 mounted on one of the U-phase, V-phase, and W-phase die pads and one of the terminals (terminal 5d) of an NU terminal, an NV terminal, and an NW terminal.

Both ends of the dummy wire 7 are connected to portions where both ends of the main wire 6 are connected, and the dummy wire 7 is provided in parallel to the main wire 6. FIG. 1 illustrates the dummy wire 7 by a thin line, and FIG. 2 illustrates a part corresponding to the dummy wire 7 by a thick line.

Tensile strength of this dummy wire 7 itself is lower than that of the main wire 6 itself. Thus, when the sealing resin 8 having high viscosity in a melting state is injected into a mold in the molding process, the dummy wire 7 is broken more easily than the main wire 6 by viscosity resistance of the sealing resin 8.

The dummy wire 7 has a diameter, a height, a length, and a material different from the main wire 6 so that the tensile strength of the dummy wire 7 itself is lower than that of the main wire 6 itself. For example, when the diameter of the dummy wire 7 is smaller than that of the main wire 6, and the height, the length, and the material thereof are the same as each other, the tensile strength of the dummy wire 7 itself is lower than that of the main wire 6 itself.

Bending strength of the dummy wire 7 itself may be lower than that of the main wire 6 itself. Mechanical strength such as the tensile strength and the bending strength of the wire itself is different from strength determined by not only the wire but also a member other than the wire such as connection strength between the wire and the member other than the wire (for example, the semiconductor switching element 1 or the terminal 5b), for example. Those types of strength are different from each other also from a viewpoint that, as the diameter of the wire gets smaller, the tensile strength of the wire decreases but the connection strength between the wire and the member other than the wire increases.

A distance of the dummy wire 7 with respect to an injection port of the sealing resin 8 in the melting state and an angle of the dummy wire 7 in an extension direction with respect to a flow direction of the sealing resin 8 in the melting state may be set in consideration of easiness of breakage of the dummy wire 7 with respect to the sealing resin 8 in the melting state in the molding process. A position of the injection port of the sealing resin 8 in the melting state corresponds to a position of a resin injection mark 8a having a convex shape in the sealing resin 8 after completion in FIG. 1.

The dummy wire 7 is preferably provided as close as possible to the injection port of the sealing resin 8 (that is to say, the resin injection mark 8a) in the melting state. Thus, in the example in FIG. 1, the dummy wire 7 is provided in parallel to the main wire 6 located closest to the resin injection mark 8a. However, the position of the dummy wire 7 is not limited thereto, but may be provided in parallel to the other main wire 6.

The dummy wire 7 is preferably provided to a part which does not influence an operation of the semiconductor device. In the configuration that the dummy wire 7 is connected in parallel to the main wire 6 as illustrated in FIG. 1, even when the dummy wire 7 is broken and comes in contact with the main wire 6, a function of a circuit can be substantially maintained by reason that the main wire 6 and the dummy wire 7 are electrically connected to each other originally.

In the present embodiment 1, the control IC 3 includes an HVIC 3a for high voltage and a LVIC 3b for low voltage as illustrated in FIG. 1 and FIG. 2. Each of the HVIC 3a and the LVIC 3b receives a signal from outside of the semiconductor device or transmits internal information to outside thereof. A signal between the HVIC 3a or the LVIC 3b and the outside are transmitted and received via a terminal 5e.

The plurality of terminals 5e are electrically independent of each other, and the terminal 5e is electrically connected to the HVIC 3a or the LVIC 3b by the lead frame 5 and a wire not shown in the diagrams, for example. As illustrated in FIG. 1, the control terminal such as the terminal 5e may be provided on a side opposite to a power terminal such as the terminals 5b to 5e with respect to the semiconductor switching element 1. According to such a configuration, a distance and insulation properties between the terminals can be easily ensured.

Power conduction of the semiconductor switching element 1 mounted on the P-side die pad is controlled by the control wire 4 based on the control signal transmitted from the HVIC 3a to the semiconductor switching element 1. Power conduction of the semiconductor switching element 1 mounted on one of the U-phase, V-phase, and W-phase die pads is controlled by the control wire 4 based on the control signal transmitted from the LVIC 3b to the semiconductor switching element 1.

Current flowing in the control wire 4 is generally smaller than that in the main wire 6. Thus, the control wire 4 of HVIC 3a and LVIC 3b may have a smaller diameter than the main wire 6. According to such a configuration, a relatively low-cost wire can be used for the control wire 4. The control wire 4 may have a larger diameter than the dummy wire 7. According to such a configuration, when sealing resin having high viscosity in a melting state is injected into a mold in a molding process, breakage of the control wire 4 caused by viscosity resistance can be suppressed.

A heatsink not shown in the diagrams is a thermal conductive member for radiating heat of the semiconductor switching element 1 to outside of the sealing resin 8.

The sealing resin 8 has insulation properties, and covers the semiconductor switching element 1, the control IC 3, the control wire 4, a part of the lead frame 5 other than the terminals 5b to 5e, the main wire 6, the dummy wire 7, and the heatsink. The terminals 5b to 5e are exposed from the sealing resin 8, thus can be electrically connected to outside of the semiconductor device.

### <Manufacturing Method>

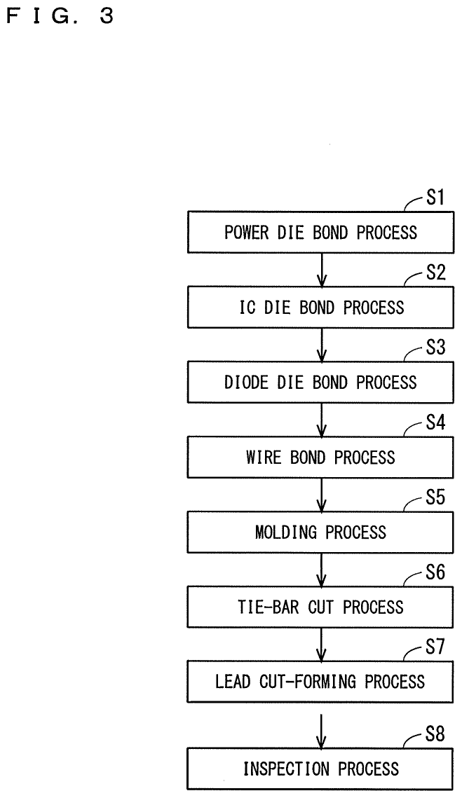

FIG. 3 is a flow chart illustrating a method of manufacturing the semiconductor device according to the present embodiment 1. A conductive member such as a metal plate is pressed to generate the lead frame 5 as a preparation process before performing a manufacturing process in FIG. 3. In this point of time, a plurality of components of the lead frame 5 are integrated by a tie-bar and a frame.

The semiconductor switching element 1 is bonded to the lead frame 5 by a bonding member in a power die bond process in Step S1. The control IC 3 is bonded to the lead frame 5 by a bonding member in an IC die bond process in Step S2. When the diode 2 is not integrated with the semiconductor switching element 1, the diode 2 is bonded to the lead frame 5 by a bonding member in a diode die bond process in Step S3. An order of the processes in Steps S1 to S3 may be changed, or at least two of the processes in Steps S1 to S3 may be performed in parallel. For example, in the configuration that the semiconductor switching element 1 and the diode 2 are provided to one semiconductor chip as illustrated in FIG. 1, Steps S1 and S3 are performed in parallel.

In a wire bond process in Step S4, the main wire 6 is electrically connected between the semiconductor switching element 1 and the terminals 5b and 5e, and both ends of the dummy wire 7 are connected to the portions where both ends of the main wire 6 are connected. The control wire 4 is electrically connected between the semiconductor switching element 1 and the control IC 3.

In the molding process in Step S5, the sealing resin 8 in the melting state is injected into a space of a mold in which the lead frame 5 is set, and is then hardened. Accordingly, the sealing resin 8 covers the semiconductor switching element 1, the control wire 4, the main wire 6, and the dummy wire 7.

The tie-bar and the frame outside of the sealing resin 8 are cut in a tie-bar cut process in Step S6, thus the plurality of components of the lead frame 5 such as the terminals 5b to 5e are separated. The terminals 5b to 5e are partially cut and bended in a lead cut-forming process in Step S7.

In an inspection process in Step S8, an inspection apparatus described hereinafter performs an electrical test, and analyzes the wire from a result thereof. Specifically, the inspection apparatus flows current in the main wire 6 and the dummy wire 7, and measures a voltage value or a resistance value of the main wire 6 and the dummy wire 7. A case of using the voltage value is described hereinafter, however, the voltage value and the resistance value substantially have a proportional relationship, thus the description of a case of using the resistance value is similar to that using the voltage value. The inspection apparatus determines a breakage state of the main wire 6 and a breakage state of the dummy wire 7 based on the measurement result of the voltage value of the main wire 6 and the dummy wire 7.

### <Inspection Process>

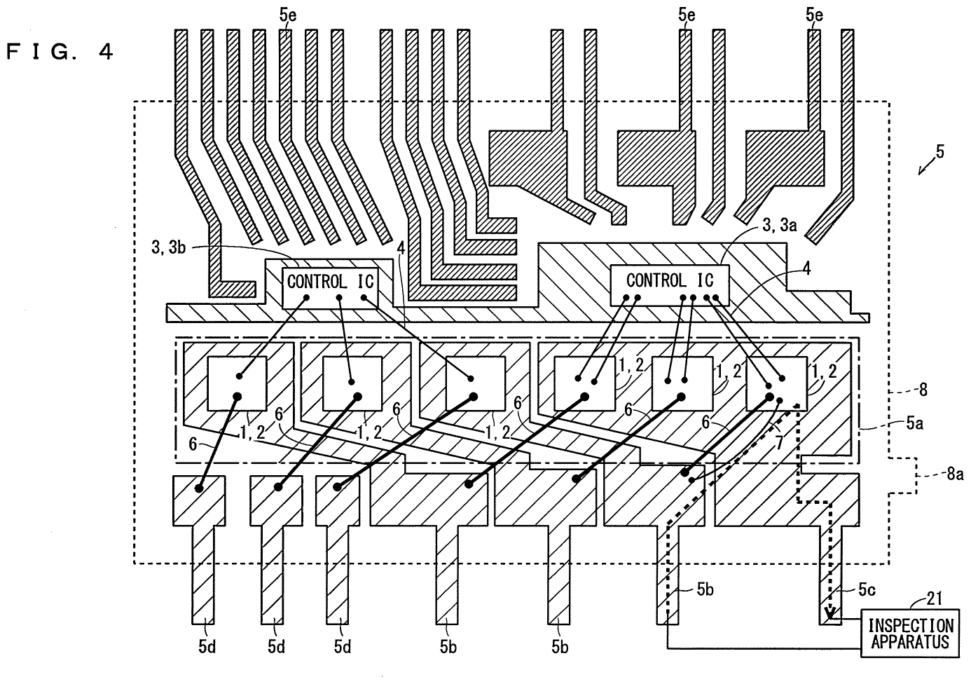

Details of the inspection process in Step S8 are described next. FIG. 4 illustrates a route along which current flows in the inspection process by an arrow. As illustrated in FIG. 4, an inspection apparatus 21 flows the current between the terminal 5b to which the dummy wire 7 is connected and the terminal 5c while the semiconductor switching element 1 to which the dummy wire 7 is connected is in an on state.

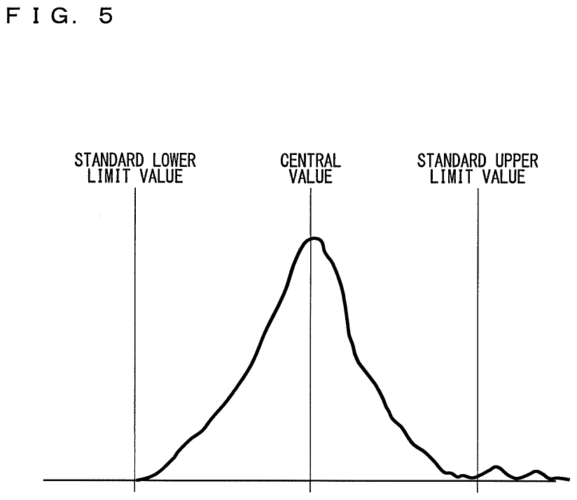

FIG. 5 is a histogram illustrating a relationship between the number of completed semiconductor devices and the voltage value of the main wire 6 and the dummy wire 7. When the dummy wire 7 is nearly broken or is broken, the voltage value of the main wire 6 and the dummy wire 7 is larger than a standard upper limit value in FIG. 5. Thus, the inspection apparatus 21 determines that the dummy wire 7 is nearly broken or is broken when the voltage value of the main wire 6 and the dummy wire 7 is larger than the standard upper limit value. A manufacturing operator can determine that there is a possibility that the main wire 6 is nearly broken when receiving such a determination result from the inspection apparatus 21.

The inspection apparatus 21 determines that the main wire 6 is nearly broken or is broken when the voltage value of the main wire 6 and the dummy wire 7 is larger than the other threshold value larger than the standard upper limit value. A manufacturing operator can determine that there is a possibility that the main wire 6 is in a worse state than a state where the main wire 6 is nearly broken, that is to say, a state where the main wire 6 is broken when receiving such a determination result from the inspection apparatus 21.

### Outline of Embodiment 1

According to the semiconductor device according to the present embodiment 1 described above, provided is the dummy wire 7 having tensile strength of itself lower than that of the main wire 6 itself. According to such a configuration, the breakage state of the main wire 6 and the breakage state of the dummy wire 7 can be determined based on the measurement result of the voltage value or the resistance value of the main wire 6 and the dummy wire 7 after the sealing resin 8 is formed. According to such a configuration, a manufacturing operator can easily determine whether or not the main wire 6 is nearly broken or is broken in a molding process, for example.

### Embodiment 2

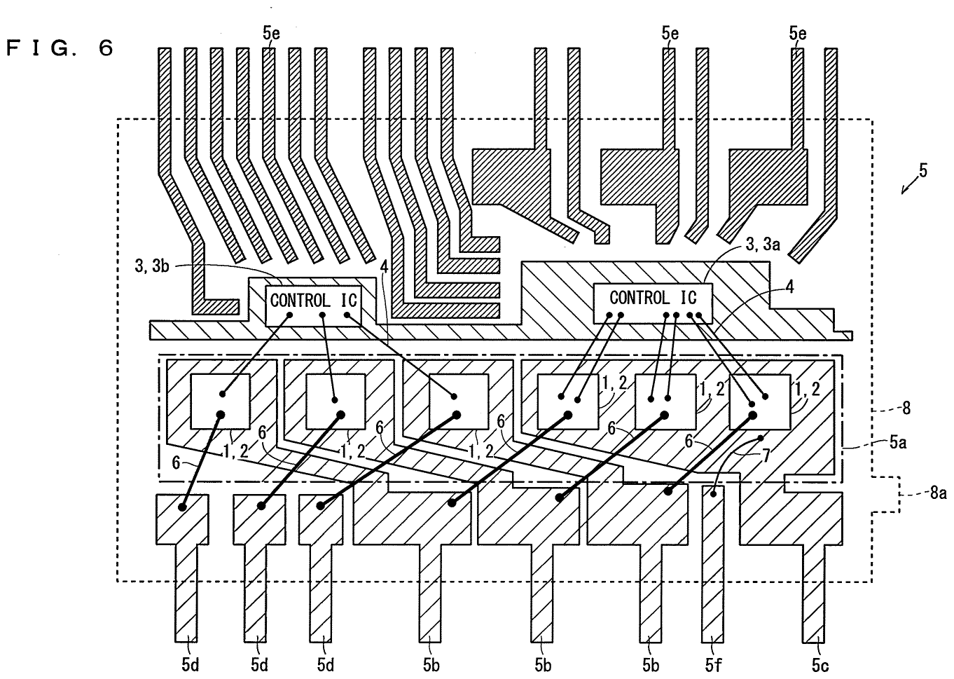

FIG. 6 is a plan view illustrating a configuration of a semiconductor device according to the present embodiment 2. In the embodiment 1, the dummy wire 7 is provided in parallel to the main wire 6, and is electrically connected between the semiconductor switching element 1 and the terminal 5b. In contrast, in the present embodiment 2, the main wire 6 is electrically connected between the semiconductor switching element 1 and the terminal 5b as a first terminal, and the dummy wire 7 is electrically connected between the terminal 5c as a second terminal and a floating terminal 5f as a third terminal. The floating terminal 5f is a terminal having floating potential independently of a circuit of the semiconductor device.

Described mainly next is a part of a method of manufacturing the semiconductor device according to the present embodiment 2 different from the method of manufacturing the semiconductor device according to the embodiment 1.

The dummy wire 7 is electrically connected between the terminal 5c and the floating terminal 5f in the wire bond process in Step S4.

In the inspection process in Step S8, the inspection apparatus 21 measures a voltage value or a resistance value of the main wire 6 and a voltage value or a resistance value of the dummy wire 7. In the configuration according to the present embodiment 2 illustrated in FIG. 6, the voltage value or the resistance value of the main wire 6 and the voltage value or the resistance value of the dummy wire 7 can be separately measured. The inspection apparatus 21 determines a breakage state of the dummy wire 7 based on the measurement result of the voltage value or the resistance value of the dummy wire 7, and determines a breakage state of the main wire 6 based on a measurement result of the voltage value or the resistance value of the main wire 6.

### Outline of Embodiment 2

According to the semiconductor device of the present embodiment 2 described above, a manufacturing operator can easily determine whether or not the main wire 6 is nearly broken or is broken in a molding process, for example, in the manner similar to the embodiment 1. The dummy wire 7 is electrically connected to the floating terminal 5f, thus complication of a circuit configuration can be suppressed.

In the above description, the first terminal is the terminal 5b, the second terminal is the terminal 5c, and the third terminal is the floating terminal 5f, however, the configuration is not limited thereto. For example, both the second terminal and the third terminal may be floating terminals. It is sufficient that potential of the second terminal and potential of the third terminal are the same as each other, and the second terminal and the third terminal may be the same terminal, for example.

### Modification Example

In the above description, the lead frame 5 is used as the die pad 5a, however, the configuration is not limited thereto. Although not shown in the diagrams, an insulating substrate having one surface provided with a conductive circuit pattern may be used as a die pad in place of the lead frame 5. In such a configuration, a circuit pattern which is not electrically connected to the semiconductor switching element 1 may be connected to a wire or a terminal by ultrasonic wave, or may also be connected to a wire or a terminal by soldering.

Each embodiment and each modification example can be arbitrarily combined, or each embodiment and each modification can be appropriately varied or omitted.

The aspects of the present disclosure are collectively described hereinafter as appendixes.

### Appendix 1

A semiconductor device, comprising:
a semiconductor element;
a terminal;
a main wire electrically connected between the semiconductor element and the terminal;
a dummy wire having both ends connected to portions where both ends of the main wire are connected and having tensile strength of itself lower than tensile strength of the main wire itself; and
sealing resin covering the semiconductor element, the main wire, and the dummy wire.

### Appendix 2

A semiconductor device, comprising:
a semiconductor element;
a first terminal, a second terminal, and a third terminal;
a main wire electrically connected between the semiconductor element and the first terminal;
a dummy wire electrically connected between the second terminal and the third terminal and having tensile strength of itself lower than tensile strength of the main wire itself; and
sealing resin covering the semiconductor element, the main wire, and the dummy wire.

### Appendix 3

The semiconductor device according to Appendix 1 or 2, further comprising
a control wire transmitting a control signal for controlling power conduction of the semiconductor element and having a diameter smaller than the main wire.

### Appendix 4

The semiconductor device according to Appendix 3, wherein
the control wire has a diameter larger than the dummy wire.

### Appendix 5

A method of manufacturing a semiconductor device, comprising:
electrically connecting a main wire between the semiconductor element and a terminal;
connecting both ends of a dummy wire having tensile strength of itself lower than tensile strength of the main wire itself to portions where both ends of the main wire are connected;
covering the semiconductor element, the main wire, and the dummy wire by sealing resin; and
determining a breakage state of the dummy wire based on a measurement result of a voltage value or a resistance value of the main wire and the dummy wire.

### Appendix 6

The method of manufacturing the semiconductor device according to Appendix 5, further comprising
determining a breakage state of the main wire based on the measurement result.

### Appendix 7

A method of manufacturing a semiconductor device, comprising:
electrically connecting a main wire between the semiconductor element and a first terminal;
electrically connecting a dummy wire having tensile strength of itself lower than tensile strength of the main wire itself between the second terminal and the third terminal;
covering the semiconductor element, the main wire, and the dummy wire by sealing resin; and
determining a breakage state of the dummy wire based on a measurement result of a voltage value or a resistance value of the dummy wire.

### Appendix 8

The method of manufacturing the semiconductor device according to Appendix 7, further comprising
determining a breakage state of the main wire based on a measurement result of a voltage value or a resistance value of the main wire.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor element;
a terminal;
a main wire electrically connected between the semiconductor element and the terminal;
a dummy wire having both ends connected to portions where both ends of the main wire are connected and having tensile strength of itself lower than tensile strength of the main wire itself; and
sealing resin covering the semiconductor element, the main wire, and the dummy wire.

2. A semiconductor device, comprising:
a semiconductor element;
a first terminal, a second terminal, and a third terminal;
a main wire electrically connected between the semiconductor element and the first terminal;
a dummy wire electrically connected between the second terminal and the third terminal and having tensile strength of itself lower than tensile strength of the main wire itself; and
sealing resin covering the semiconductor element, the main wire, and the dummy wire.

3. The semiconductor device according to claim 1, further comprising
a control wire transmitting a control signal for controlling power conduction of the semiconductor element and having a diameter smaller than the main wire.

4. The semiconductor device according to claim 3, wherein
the control wire has a diameter larger than the dummy wire.

5. A method of manufacturing a semiconductor device, comprising:
electrically connecting a main wire between the semiconductor element and a terminal;
connecting both ends of a dummy wire having tensile strength of itself lower than tensile strength of the main wire itself to portions where both ends of the main wire are connected;
covering the semiconductor element, the main wire, and the dummy wire by sealing resin; and
determining a breakage state of the dummy wire based on a measurement result of a voltage value or a resistance value of the main wire and the dummy wire.

6. The method of manufacturing the semiconductor device according to claim 5, further comprising
determining a breakage state of the main wire based on the measurement result.

7. A method of manufacturing a semiconductor device, comprising:
electrically connecting a main wire between the semiconductor element and a first terminal;
electrically connecting a dummy wire having tensile strength of itself lower than tensile strength of the main wire itself between the second terminal and the third terminal;
covering the semiconductor element, the main wire, and the dummy wire by sealing resin; and
determining a breakage state of the dummy wire based on a measurement result of a voltage value or a resistance value of the dummy wire.

8. The method of manufacturing the semiconductor device according to claim 7, further comprising
determining a breakage state of the main wire based on a measurement result of a voltage value or a resistance value of the main wire.

9. The semiconductor device according to claim 2, further comprising
a control wire transmitting a control signal for controlling power conduction of the semiconductor element and having a diameter smaller than the main wire.

10. The semiconductor device according to claim 9, wherein
the control wire has a diameter larger than the dummy wire.
